(19) United States
(12) Patent Application Publication
(10) Pub. No.: US 2006/0216895 A1
(43) Pub. Date: Sep. 28, 2006

(54) Power semiconductor device having buried gate bus and process for fabricating the same

(75) Inventors: Jun Zeng, Taipei County (TW); Po-I Sun, Taipei County (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Pyramis Corporation

(21) Appl. No.: 11/165,077

(22) Filed: Jun. 23, 2005

(30) Foreign Application Priority Data
Mar. 28, 2005 (TW) 094109635

(51) Int. Cl. H01L 21/336; H01L 21/3205

(52) U.S. Cl. 438/270; 438/589; 438/272

(57) ABSTRACT

A power semiconductor device includes a substrate, a gate oxide layer, a gate bus layer, an inter-layer dielectric layer and a metal bus layer. The substrate has a trench structure therein. The gate oxide layer is formed on surfaces of the substrate and the trench structure. The gate bus layer is formed on the gate oxide layer inside the trench structure. The inter-layer dielectric layer is formed on the gate oxide layer and a portion of the gate bus layer, thereby defining a contact window. The metal bus layer is formed on the inter-layer dielectric layer and the trench structure, and connected to the gate bus layer via the contact window.

### FIELD OF THE INVENTION

The present invention relates to a power semiconductor device, and more particularly to a power semiconductor device having a buried gate bus. The present invention also relates to a process for fabricating such a power semiconductor device.

### BACKGROUND OF THE INVENTION

Recently, power semiconductor devices such as power MOSFET (metal oxide semiconductor field effect transistor), IGBT (Insulated Gate Bipolar Transistor), JFET (Junction Field Effect Transistor) or Rectifier, have achieved a great deal of advance in their performance and manufacturing process technology. One of the major trends for further improving power device characteristics and reducing their manufacturing cost is to employ the so-called trench technology. Up to today, the trench technology has been successfully used in the commercial power MOSFET and IGBT products.

As well known, in order to process and regulate high electrical power, typical power devices normally consist of many identical cells connected together in parallel. Each control terminal of the basic cell called the, gate terminal is connected together by the so-called gate bus across the whole die. The material used to form the gate bus has traditionally been a highly doped polysilcon, which has a sheet resistance less than 20 ohm/square. The gate bus is defined by making use of photolithography technique followed by the polysilicon etch process.

Please refer to FIGS. 1(a), 1(b) and 1(c), which illustrate different gate bus configurations implemented in prior art. The power semiconductor device comprises an EPI/substrate 11, a gate oxide layer 12, a gate bus layer 13, an ILD (Inter-Layer Dielectrics) layer 14 and a metal bus layer 15. The gate oxide layer 12 is formed on the EPI/substrate 11. The gate bus layer 13 is formed on the gate oxide layer 12. The ILD layer 14 is formed above the gate oxide layer 12 and the gate bus layer 13. The metal bus layer 15 is formed on the ILD layer 14 and connected to the gate bus layer 13 via the contact window in the ILD layer 14. In these prior arts, the gate bus layer 13 is formed by depositing a polysilicon layer on the gate oxide layer 12 after the gate oxide layer 12 is formed on the EPI/substrate 11, and then defined by making use of a photolithography and etch step. The process needs one additional photolithographic process step followed by the polysilicon etch process, and afterwards the photoresist covered on resulting structure needs to be removed. As a consequence, the fabrication cost is increased and the production throughput is reduced. On the other hand, since the performance of depositing and etching the ILD layer 14 is dependent on the structure of the gate bus layer 13, the process complexity is increased.

In views of the above-described disadvantages resulted from the prior art, the applicant keeps on carving unflaggingly to develop a power semiconductor device having a buried gate bus according to the present invention through wholehearted experience and research.

### SUMMARY OF THE INVENTION

An object of the present invention is to provide a power semiconductor device having a buried gate bus and a fabricating process thereof, in which no additional photolithography step is required to form the buried gate bus, thereby reducing the process complexity and fabrication cost and increasing the production throughput.

In accordance with a first aspect of the present invention, there is provided a power semiconductor device having a buried gate bus. The power semiconductor device comprises a substrate, a gate oxide layer, a gate bus layer, an inter-layer dielectric layer and a metal bus layer. The substrate has a trench structure therein. The gate oxide layer is formed on surfaces of the substrate and the trench structure. The gate bus layer is formed on the gate oxide layer inside the trench structure. The inter-layer dielectric layer is formed on the gate oxide layer and a portion of the gate bus layer, thereby defining a contact window. The metal bus layer is formed on the inter-layer dielectric layer and the trench structure, and connected to the gate bus layer via the contact window.

Preferably, the power semiconductor device is selected from a group consisting of power MOSFET (metal oxide semiconductor field effect transistor) and IGBT (Insulated Gate Bipolar Transistor).

Preferably, the substrate is an EPI/substrate.

In an embodiment, the gate bus layer is filled in the trench structure.

In another embodiment, the gate bus layer is formed on internal walls of the trench structure.

In a further embodiment, the gate bus layer is formed on internal walls of the trench structure, and a portion of the inter-layer dielectric layer is further formed on the bottom of the trench structure.

Preferably, the gate oxide layer is a thermal oxide layer.

Preferably, the gate bus layer is a polysilicon layer.

Preferably, the inter-layer dielectric layer is a deposition oxide layer.

In accordance with a second aspect of the present invention, there is provided a process for fabricating a power semiconductor device having a buried gate bus. The process comprising steps of (a) providing a substrate; (b) etching the substrate to form a trench structure in the substrate; (c) forming a gate oxide layer on the surfaces of the substrate and the trench structure; (d) depositing a polysilicon layer on the gate oxide layer; (e) etching the polysilicon layer to form a gate bus layer on the gate oxide layer inside the trench structure; (f) forming an inter-layer dielectric layer on the gate oxide layer and a portion of the gate bus layer, thereby defining a contact window; and (g) forming a metal bus layer on the inter-layer dielectric layer and the trench structure, and connecting the metal bus layer to the gate bus layer via the contact window.

In accordance with a third aspect of the present invention, there is provided a power semiconductor device having a buried gate bus. The power semiconductor device comprises a substrate, a gate bus layer, an inter-layer dielectric layer and a metal bus layer. The substrate has a trench structure therein. The gate bus layer is formed on internal walls of the trench structure. The inter-layer dielectric layer is formed on the substrate and a portion of the gate bus layer, thereby defining a contact window. The metal bus layer is formed on the inter-layer dielectric layer and the trench structure, and connected to the gate bus layer via the contact window.

Preferably, the power semiconductor device is JFET (Junction Field Effect Transistor).

Preferably, the power semiconductor device further comprises a first crystalline silicon layer between the substrate and the gate bus layer.

Preferably, the substrate and the first crystalline silicon layer are N-type and P-type crystalline silicon layers, respectively.

The above contents of the present invention will become more readily apparent to those ordinarily skilled in the art after reviewing the following detailed description and accompanying drawings, in which:

### BRIEF DESCRIPTION OF THE DRAWINGS

FIGS. 1(a)˜1(c) illustrate different gate bus configurations implemented in prior art;

FIG. 2 is a schematic view of a power semiconductor device having a buried gate bus according to a preferred embodiment of the present invention;

FIGS. 3(a)˜3(g) illustrate a process for fabricating the power semiconductor device of FIG. 2;

FIGS. 4(a)˜4(h) illustrate a process for fabricating the power semiconductor device according to another preferred embodiment of the present invention;

FIGS. 5(a)˜5(h) illustrate a process for fabricating the power semiconductor device according to another preferred embodiment of the present invention;

FIG. 6 is a schematic view of a power semiconductor device having a buried gate bus according to another preferred embodiment of the present invention; and

FIGS. 7(a)˜7(g) illustrate a process for fabricating the power semiconductor device of FIG. 6.

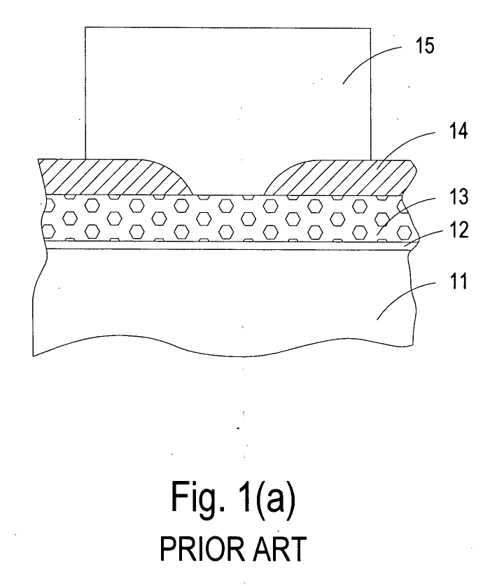

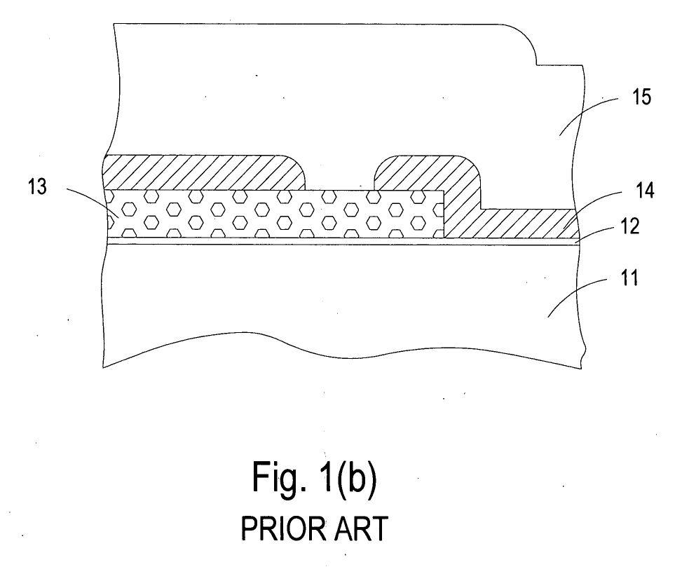

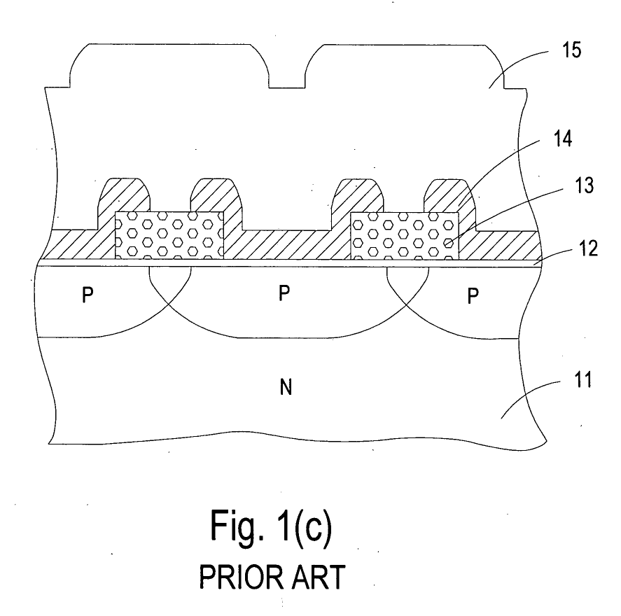

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

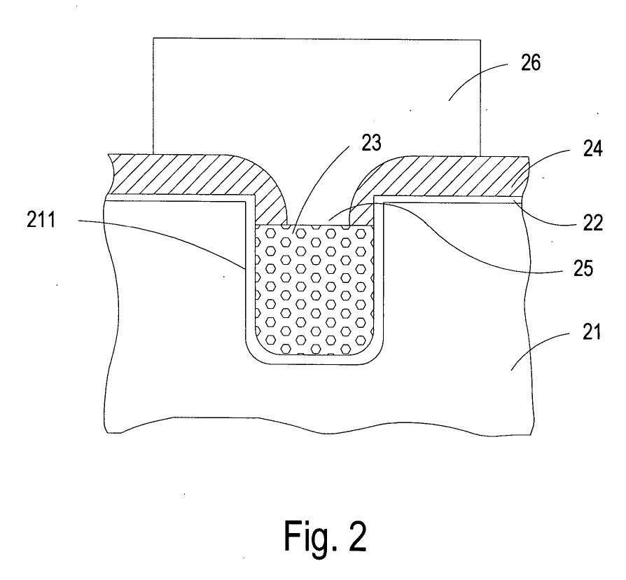

Referring to FIG. 2, a schematic view of a power semiconductor device having a buried gate bus according to a preferred embodiment of the present invention is illustrated. The power semiconductor device comprises an EPI/substrate 21, a gate oxide layer 22, a gate bus layer 23, an ILD (inter-layer dielectric) layer 24 and a metal bus layer 26. The EPI/substrate 21 has a trench structure 211 therein. The gate oxide layer 22 is formed on the surfaces of the EPI/substrate 21 and the trench structure 211. The gate bus layer 23 is formed on the gate oxide layer 12 inside the trench structure 211. The ILD layer 24 is formed on the gate oxide layer 22 and a portion of the gate bus layer 23, thereby defining a contact window 25. The metal bus layer 26 is formed on the ILD layer 24 and the trench structure 211, and connected to the gate bus layer 23 via the contact window 25.

An exemplary power semiconductor device described in the above embodiment includes power MOSFET or IGBT. The gate bus layer 23 is a polysilicon layer filled in the trench structure 211. The gate oxide layer 22 is a thermal oxide layer, and the ILD layer 24 is a deposition oxide layer.

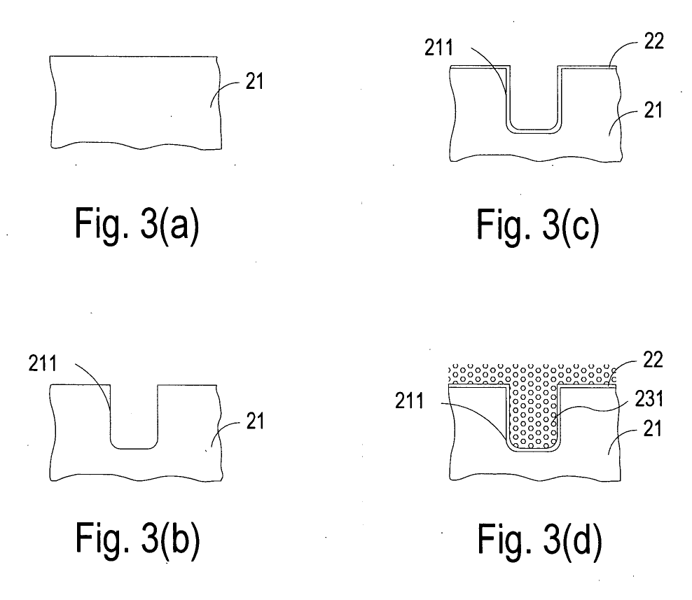

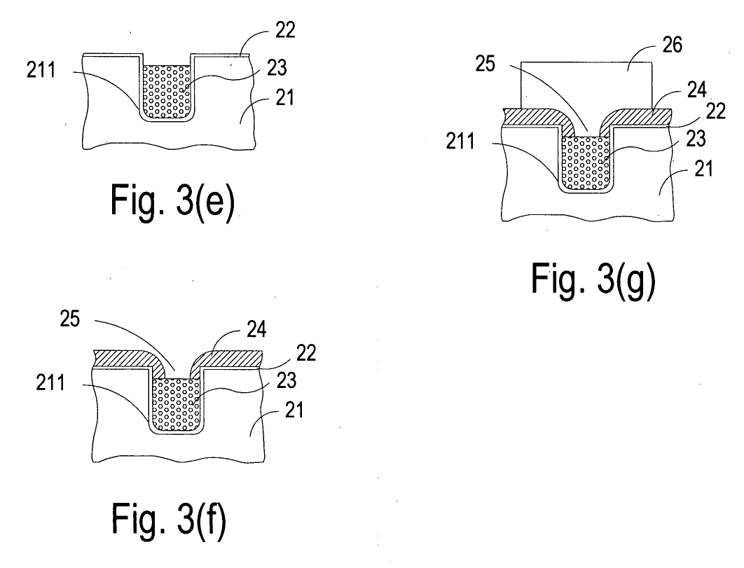

A process for fabricating the power semiconductor device of FIG. 2 is illustrated with reference to FIGS. 3(a)˜3(g).

First of all, as shown in FIG. 3(a), an EPI/substrate 21 is provided. Then, in FIG. 3(b), an anisotropic dry etch step is performed to etch the EPI/substrate 21 so as to form a trench structure 211 in the EPI/substrate 21. Then, by a thermal oxidation step, a portion of the surface of the EPI/substrate 21 is oxidized and thus a gate oxide layer 22 is formed on the surfaces of the EPI/substrate 21 and the trench structure 211, as is shown in FIG. 3(c). Then, a polysilicon layer 231 is deposited on the gate oxide layer 22 and filled in the trench structure 211, as can be seen in FIG. 3(d). In FIG. 3(e), another anisotropic dry etch step is performed to etch the polysilicon layer 231 so as to form a gate bus layer 23 inside the trench structure 211. After an ILD layer 24 is deposited on the gate oxide layer 22 and the gate bus layer 23, a portion of the ILD layer 24 is removed by a photolithography and etch step, thereby defining a contact window 25 to the gate bus layer 23, as is shown in FIG. 3(f). Afterwards, a metal bus layer 26 is formed on the ILD layer 24 and the trench structure 211, and connected to the gate bus layer 23 via the contact window 25. Therefore, the resulting structure of the power semiconductor device having a buried gate bus, as shown in FIG. 3(g) is implemented.

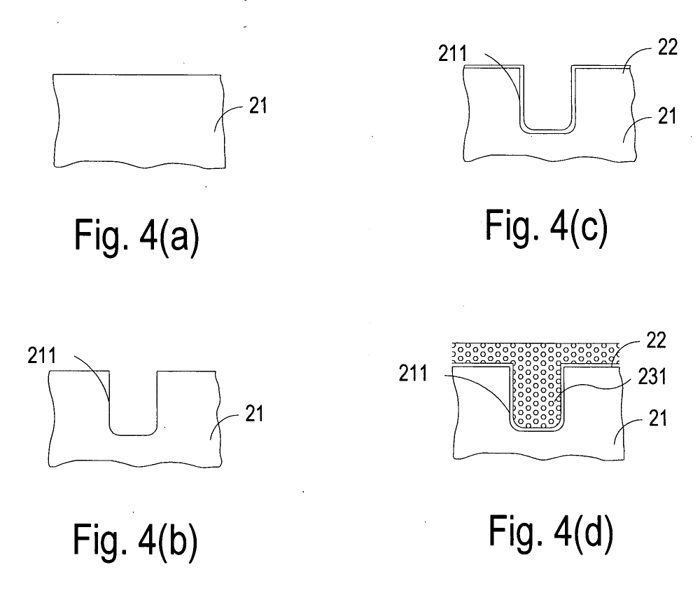

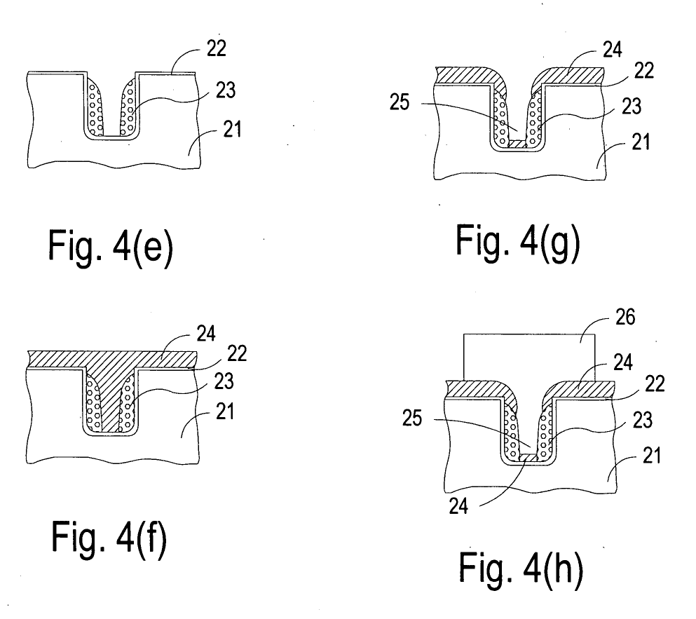

Depending on the thickness of the polysilicon layer and the width of the trench structure, the structure of the power semiconductor device and the fabricating process thereof are varied. A further embodiment of a process for fabricating the power semiconductor device having a buried gate bus is illustrated in FIGS. 4(a)˜4(h).

First of all, as shown in FIG. 4(a), an EPI/substrate 21 is provided. Then, in FIG. 4(b), an anisotropic dry etch step is performed to etch the EPI/substrate 21 so as to form a trench structure 211 in the EPI/substrate 21. Then, by a thermal oxidation step, a portion of the surface of the EPI/substrate 21 is oxidized and thus a gate oxide layer 22 is formed on the surfaces of the EPI/substrate 21 and the trench structure 211, as is shown in FIG. 4(c). Then, a polysilicon layer 231 is deposited on the gate oxide layer 22 and filled in the trench structure 211, as can be seen in FIG. 4(d). Then, as shown in FIG. 4(e), another anisotropic dry etch step is performed to etch the polysilicon layer 231 until the bottom of the trench structure 211 so as to expose a portion of the gate oxide layer 22 underlying the bottom of the trench structure 211. Meanwhile, the polysilicon layer 231 is formed on the internal walls of the trench structure 211 to form the gate bus layer 23. Then, an ILD layer 24 is deposited on the gate oxide layer 22 and the gate bus layer 23, as is shown in FIG. 4(f). Then, by a photolithography and etch step, a portion of the ILD layer 24 is removed. In this circumstance, the remaining ILD layer 24 is covered on the gate oxide layer 22, a portion of the gate bus layer 23 and the bottom of the trench structure 211 to expose a portion of the gate bus layer 23, thereby defining a contact window 25 as shown in FIG. 4(g). Afterwards, a metal bus layer 26 is formed on the ILD layer 24, filled in the contact window 25, and connected to the gate bus layer 23 via the contact window 25. Therefore, the resulting structure of the power semiconductor device having a buried gate bus, as shown in FIG. 4(h) is implemented. By the way, depending on the thickness of the ILD layer 24 and the etch time, the ILD layer 24 may remain on the bottom of the contact window 25 or alternatively be removed.

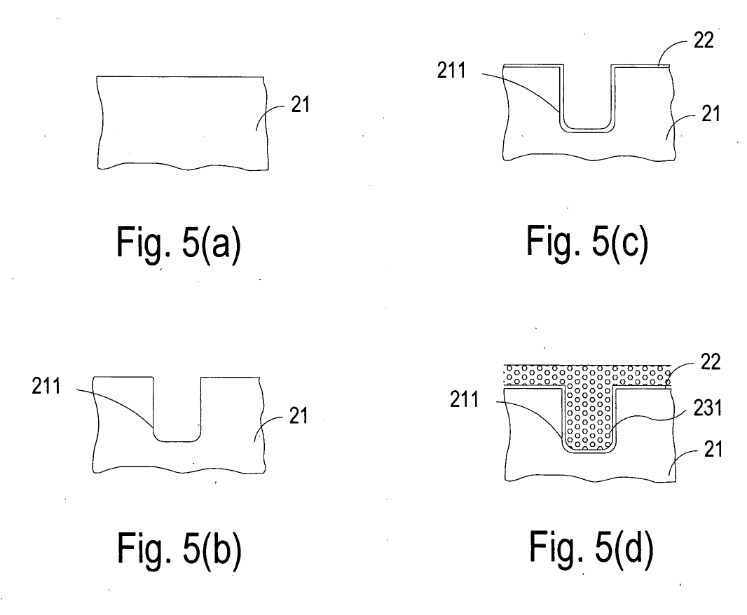

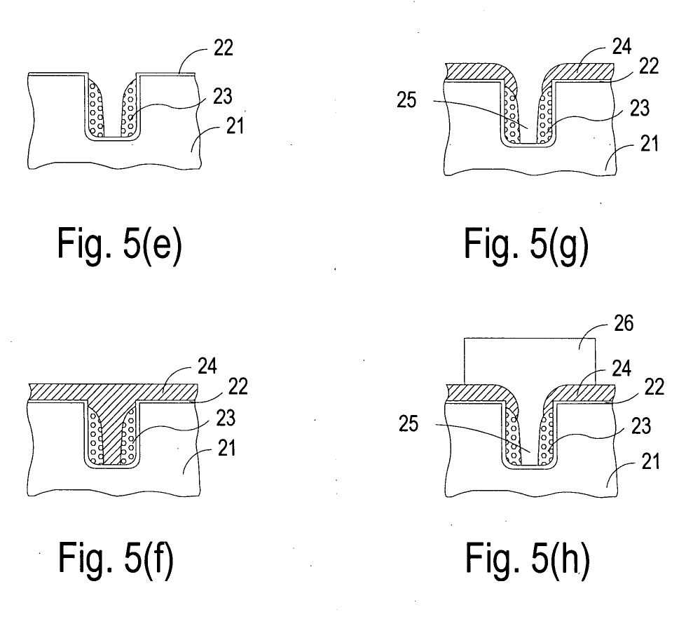

A further embodiment of a process for fabricating the power semiconductor device having a buried gate bus is illustrated in FIGS. 5(a)˜5(h).

First of all, as shown in FIG. 5(a), an EPI/substrate 21 is provided. Then, in FIG. 5(b), an anisotropic dry etch step is performed to etch the EPI/substrate 21 so as to form a trench structure 211 in the EPI/substrate 21. Then, by a thermal oxidation step, a portion of the surface of the EPI/substrate 21 is oxidized and thus a gate oxide layer 22 is formed on the surfaces of the EPI/substrate 21 and the trench structure 211, as is shown in FIG. 5(c). Then, a polysilicon layer 231 is deposited on the gate oxide layer 22 and filled in the trench structure 211, as can be seen in FIG. 5(d). Then, as shown in FIG. 5(e), another anisotropic dry etch step is performed to etch the polysilicon layer 231 until the bottom of the trench structure 211 so as to expose a portion of the gate oxide layer 22 underlying the bottom of the trench structure 211. Meanwhile, the polysilicon layer 231 is formed on the internal walls of the trench structure 211 to form the gate bus layer 23. Then, an ILD layer 24 is deposited on the gate oxide layer 22 and the gate bus layer 23, as is shown in FIG. 5(f). Then, by a photolithography and etch step, a portion of the ILD layer 24 is removed. In this circumstance, the remaining ILD layer 24 is covered on the gate oxide layer 22 and a portion of the gate bus layer 23 to expose a portion of the gate bus layer 23, thereby defining a contact window 25 as shown in FIG. 5(g). Afterwards, a metal bus layer 26 is formed on the ILD layer 24, filled in the contact window 25, and connected to the gate bus layer 23 via the contact window 25. Therefore, the resulting structure of the power semiconductor device having a buried gate bus, as shown in FIG. 5(h) is implemented.

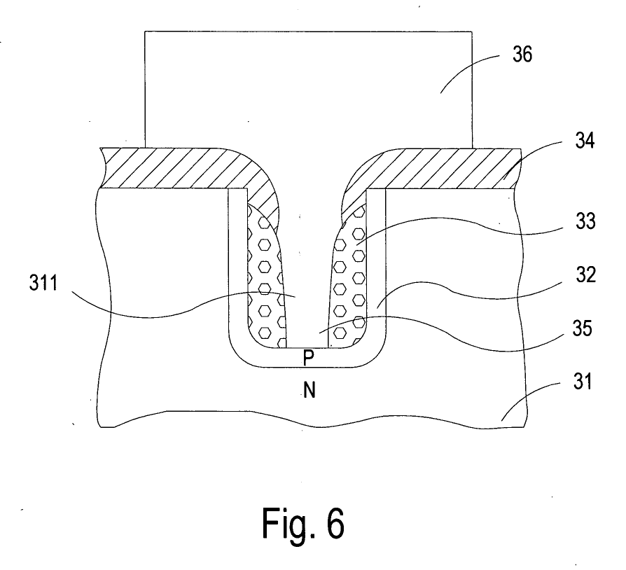

Referring to FIG. 6, a schematic view of a power semiconductor device having a buried gate bus according to another preferred embodiment of the present invention is illustrated. The power semiconductor device comprises an EPI/substrate 31, a first crystalline silicon layer 32, a gate bus layer 33, an ILD (inter-layer dielectric) layer 34 and a metal bus layer 36. The EPI/substrate 31 has a trench structure 311 therein. The first crystalline silicon layer 32 is formed on the internal walls of the trench structure 311. The gate bus layer 33 is formed on side walls of the first crystalline silicon layer 32 inside the trench structure 311. The ILD layer 34 is formed on a portion of the gate bus layer 33 and the surface of the EPI/substrate 31, thereby defining a contact window 35. The metal bus layer 36 is formed on the ILD layer 34, filled in the trench structure 311, and connected to the gate bus layer 33 via the contact window 35. In this embodiment, the first crystalline silicon layer 32 between the EPI/substrate 31 and the gate bus layer 33 is a P-type crystalline silicon layer, and the EPI/substrate 31 is an N-type crystalline silicon layer. The structure described in this embodiment is applicable to fabricate JFET. Since the gate bus layer 33 is formed on side walls of the trench structure 311, the cross-sectional area of the gate bus layer 33 is smaller than that of the trench structure 311. Likewise, the gate bus layer 33 is a polysilicon layer, and the ILD layer 34 is a deposition oxide layer.

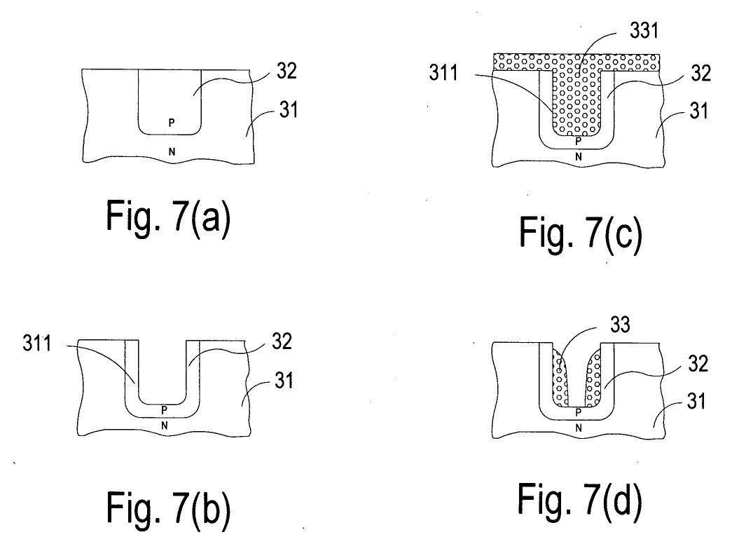

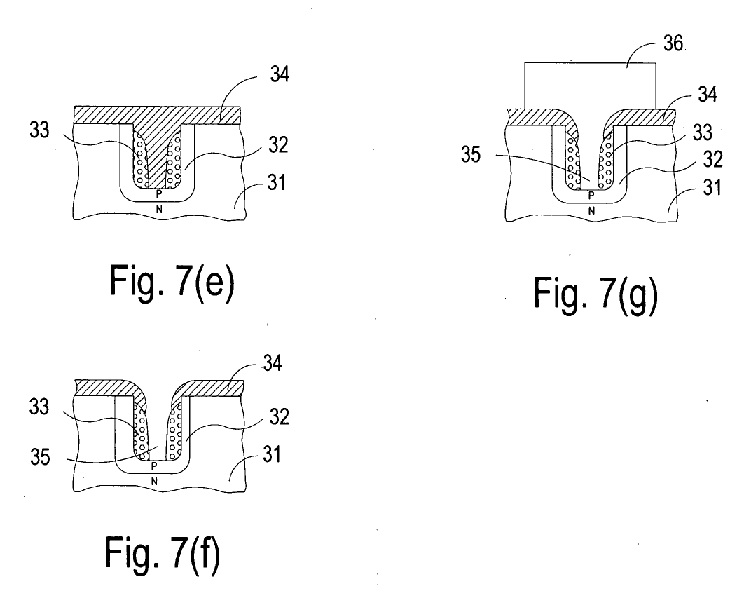

The process for fabricating the power semiconductor device as shown in FIG. 6 will be illustrated in FIGS. 7(a)˜7(g).

First of all, as shown in FIG. 7(a), an EPI/substrate 31 including a first crystalline silicon layer 32 is provided. The EPI/substrate 31 and the first crystalline silicon layer 32 are N-type and P-type crystalline silicon layers, respectively. Then, in FIG. 7(b), an anisotropic dry etch step is performed to etch the crystalline silicon layer 32 in the EPI/substrate 31 so as to form a trench structure 311 in the EPI/substrate 31. Then, a polysilicon layer 331 is deposited on the EPI/substrate 31 and filled in the trench structure 311, as can be seen in FIG. 7(c). Then, as shown in FIG. 7(d), another anisotropic dry etch step is performed to etch the polysilicon layer 331 until the bottom of the trench structure 311 so as to expose a portion of the first crystalline silicon layer 32 underlying the bottom of the trench structure 311. Meanwhile, the polysilicon layer 331 is formed on the internal walls of the trench structure 311 to form the gate bus layer 33. Then, an ILD layer 34 is deposited on the gate bus layer 33 and filled in the trench structure 311, as is shown in FIG. 7(e). Then, by a photolithography and etch step, a portion of the ILD layer 34 is removed. In this circumstance, the remaining ILD layer 34 is covered on the surface of the EPI/substrate 31 and a portion of the gate bus layer 33 to expose a portion of the gate bus layer 33, thereby defining a contact window 35 as shown in FIG. 7(f). Afterwards, a metal bus layer 36 is formed on the ILD layer 34, filled in the contact window 35, and connected to the gate bus layer 33 via the contact window 35. Therefore, the resulting structure of the power semiconductor device having a buried gate bus, as shown in FIG. 7(g) is implemented.

From the above description, the structure and fabricating process of the invention can be applied to many power semiconductor devices such as power MOSFET (metal oxide semiconductor field effect transistor), IGBT (Insulated Gate Bipolar Transistor) and JFET (Junction Field Effect Transistor). Since the buried gate bus is formed without the additional photolithographic process step, the fabrication cost is reduced and the production throughput is increased.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power semiconductor device having a buried gate bus, comprising:
a substrate having a trench structure therein;
a gate oxide layer formed on surfaces of said substrate and said trench structure;
a gate bus layer formed on said gate oxide layer inside said trench structure;
an inter-layer dielectric layer formed on said gate oxide layer and a portion of said gate bus layer, thereby defining a contact window; and
a metal bus layer formed on said inter-layer dielectric layer and said trench structure, and connected to said gate bus layer via said contact window.

2. The power semiconductor device according to claim 1 wherein said power semiconductor device is selected from a group consisting of power MOSFET (metal oxide semiconductor field effect transistor) and IGBT (Insulated Gate Bipolar Transistor).

3. The power semiconductor device according to claim 1 wherein said substrate is an EPI/substrate.

4. The power semiconductor device according to claim 1 wherein said gate bus layer is filled in said trench structure.

5. The power semiconductor device according to claim 1 wherein said gate bus layer is formed on internal walls of said trench structure.

6. The power semiconductor device according to claim 1 wherein said gate bus layer is formed on internal walls of said trench structure, and a portion of said inter-layer dielectric layer is further formed on the bottom of said trench structure.

7. The power semiconductor device according to claim 1 wherein said gate oxide layer is a thermal oxide layer.

8. The power semiconductor device according to claim 1 wherein said gate bus layer is a polysilicon layer.

9. The power semiconductor device according to claim 1 wherein said inter-layer dielectric layer is a deposition oxide layer.

10. A process for fabricating a power semiconductor device having a buried gate bus, comprising steps of:
(a) providing a substrate;
(b) etching said substrate to form a trench structure in said substrate;.
(c) forming a gate oxide layer on the surfaces of said substrate and said trench structure;
(d) depositing a polysilicon layer on said gate oxide layer;
(e) etching said polysilicon layer to form a gate bus layer on said gate oxide layer inside said trench structure;
(f) forming an inter-layer dielectric layer on said gate oxide layer and a portion of said gate bus layer, thereby defining a contact window; and
(g) forming a metal bus layer on aid inter-layer dielectric layer and said trench structure, and connecting said metal bus layer to said gate bus layer via said contact window.

11. The process according to claim 10 wherein said step (b) is performed by an anisotropic dry etch procedure.

12. The process according to claim 10 wherein said step (c) is performed by a thermal oxidation procedure.

13. The process according to claim 10 wherein said step (e) is performed by another anisotropic dry etch procedure.

14. A power semiconductor device having a buried gate bus, comprising:
a substrate having a trench structure therein;
a gate bus layer formed on internal walls of said trench structure;
an inter-layer dielectric layer formed on said substrate and a portion of said gate bus layer, thereby defining a contact window; and
a metal bus layer formed on said inter-layer dielectric layer and said trench structure, and connected to said gate bus layer via said contact window.

15. The power semiconductor device according to claim 14 wherein said power semiconductor device is JFET (Junction Field Effect Transistor).

16. The power semiconductor device according to claim 14 further comprising a first crystalline silicon layer between said substrate and said gate bus layer.

17. The power semiconductor device according to claim 16 wherein said substrate and said first crystalline silicon layer are N-type and P-type crystalline silicon layers, respectively.

18. The power semiconductor device according to claim 14 wherein said gate bus layer is a polysilicon layer.

19. The power semiconductor device according to claim 14 wherein said inter-layer dielectric layer is a deposition oxide layer.
